(19) United States
(12) Patent Application Publication
(10) Pub. No.: US 2023/0009844 A1
(43) Pub. Date: Jan. 12, 2023

(54) OPTICAL FILTER SUITABLE FOR CORRECTING THE ELECTRONIC NOISE OF A SENSOR

(71) Applicant: ISORG, Limoges CEDEX 3 (FR)

(72) Inventors: Benjamin BOUTHINON, GRENOBLE (FR); Pierre MULLER, GRENOBLE (FR); Noémie BALLOT, GRENOBLE (FR)

(21) Appl. No.: 17/783,782

(22) PCT Filed: Dec. 9, 2020
(86) PCT No.: PCT/EP2020/085380

§ 371 Date: Jun. 9, 2022

(30) Foreign Application Priority Data
Dec. 11, 2019 (FR) 1914198

(51) Int. Cl. H01L 27/146; G02B 5/20; G06V 40/13

(52) U.S. Cl. CPC H01L 27/14645; H01L 27/14627; G02B 5/208; H01L 27/14685; G06V 40/1318

(57) ABSTRACT

An optical filter for an image sensor includes first opaque zones. Each of the first opaque zones occupies a surface area equal to the surface area of at least one first lens in this same first zone.

### RELATED APPLICATIONS

The present patent application claims the priority benefit of French patent application FR19/14198 which is herein incorporated by reference.

### FIELD

The present disclosure concerns an image acquisition system.

### BACKGROUND

An image acquisition system generally comprises an image sensor and an optical system, interposed between the sensitive portion of the image sensor and the object to be imaged and which enables to form a sharp image of the object to be imaged on the sensitive portion of the image sensor. The optical system may be an optical filter and more particularly an angular filter.

An angular filter is a device enabling to filter an incident radiation according to the incidence of this radiation and thus to block rays having an incidence greater than a desired angle, called maximum incidence angle.

This enables to avoid crosstalk phenomena between pixels.

### SUMMARY

There is a need to improve image acquisition systems.

An embodiment overcomes all or part of the disadvantages of image acquisition systems.

An embodiment provides an optical filter for an image sensor comprising first opaque zones, each first zone occupying a surface area equal to the surface of at least a first lens comprised in this first zone.

An embodiment provides an optical filter for an image sensor, comprising:

an array of lenses formed of first and of second adjacent lenses and located on the first surface side of a substrate, the first lenses being comprised in first opaque zones and the second lenses being comprised in second zones, each first zone occupying a surface area equal to the surface area of at least one first lens comprised in this first zone;

openings, on the second surface side of said substrate, at least opposite the second lenses; and

an opaque layer opposite the first lenses on the second surface side of said substrate.

According to an embodiment, the transmittance of the first zones is lower than approximately 0.1%, preferably lower than approximately 0.00001%.

According to an embodiment, the optical filter comprises second transparent zones, each second zone occupying a surface area equal to the surface area of at least one second lens comprised in this second zone.

According to an embodiment, the first lenses and the second lenses are coplanar.

According to an embodiment, the first zones and the second zones are adjacent and organized in rows and in columns.

According to an embodiment, the first zones are organized in columns which are adjacent and located on one of the edges of the filter.

According to an embodiment, the first zones are organized in columns which are distributed on two edges of the filter.

According to an embodiment, the radius of curvature of the first lenses is smaller than the radius of curvature of the second lenses.

According to an embodiment, the radius of curvature of the first lenses is greater than the radius of curvature of the second lenses.

According to an embodiment, the optical filter successively comprises:

an array of lenses, formed of the first and second adjacent lenses, located on the first surface side of a substrate; and

a first layer, on the second surface side of said substrate, which is solid opposite the first lenses and comprises openings opposite the second lenses.

According to an embodiment, the optical filter successively comprises:

an array of lenses, located on the first surface side of a substrate;

a first layer comprising an array of openings on the second surface side of said substrate; and

a second opaque layer, in each first zone.

According to an embodiment, the optical filter successively comprises:

an array of lenses formed of the first locally deteriorated lenses and of the second adjacent lenses, located on the first surface side of a substrate; and

a first layer comprising an array of openings on the second surface side of said substrate.

An embodiment provides a method of manufacturing the optical filter, comprising, among others, the steps of:

forming, by printing, the array of lenses on the first surface side of the substrate;

depositing a first layer of a resist on the second surface side of the substrate; and

forming openings, in the first layer, by photolithography through the lenses.

According to an embodiment, the second layer is formed in the openings in the first zones or on the first or second surface side of said openings.

According to an embodiment, the second layer is formed in the first zones.

According to an embodiment, the first lenses are partially deteriorated by a laser.

An embodiment provides a system comprising:

an optical filter capable of being considered as an angular filter;

a source of a radiation; and

an image sensor comprising photodetectors capable of detecting said radiation.

An embodiment provides a fingerprint sensor comprising a system.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates, in a partial simplified cross-section view, an embodiment of an image acquisition system;

FIG. 2 illustrates, in a partial simplified top view, an embodiment of an image acquisition system;

FIG. 3 illustrates, in a partial simplified top view, another embodiment of an image acquisition system;

FIG. 4 illustrates, in a partial simplified cross-section view, still another embodiment of an image acquisition system;

FIG. 5 illustrates, in a partial simplified cross-section view, a step of a first implementation mode of an angular filter manufacturing method;

FIG. 6 illustrates, in a partial simplified cross-section view, another step of the first implementation mode of the angular filter manufacturing method;

FIG. 7 illustrates, in a partial simplified cross-section view, still another step of the first implementation mode of the angular filter manufacturing method;

FIG. 8 illustrates, in a partial simplified cross-section view, a step of a second implementation mode of an angular filter manufacturing method;

FIG. 9 illustrates, in a partial simplified cross-section view, another step of the second implementation mode of the angular filter manufacturing method;

FIG. 10 illustrates, in a partial simplified cross-section view, still another step of the second implementation mode of the angular filter manufacturing method;

FIG. 11 illustrates, in a partial simplified cross-section view, still another step of the second implementation mode of the angular filter manufacturing method;

FIG. 12 illustrates, in a partial simplified cross-section view, a step of a third implementation mode of an angular filter manufacturing method;

FIG. 13 illustrates, in a partial simplified cross-section view, another step of the third implementation mode of the angular filter manufacturing method;

FIG. 14 illustrates, in a partial simplified cross-section view, still another step of the third implementation mode of the angular filter manufacturing method;

FIG. 15 illustrates, in a partial simplified cross-section view, still another step of the third implementation mode of the angular filter manufacturing method; and

FIG. 16 illustrates, in a partial simplified cross-section view, a step of a fourth implementation mode of an angular filter manufacturing method.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the forming of the image sensor and of the elements other than the angular filter have not been detailed, the described embodiments and implementation modes being compatible with usual embodiments of the sensor and of these other elements.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, unless specified otherwise, a layer or a film is called opaque to a radiation when the transmittance of the radiation through the layer of the film is smaller than 10%. In the following description, a layer or a film is called transparent to a radiation when the transmittance of the radiation through the layer or the film is greater than 10%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system transparent to said radiation. In the rest of the disclosure, the term “useful radiation” designates the electromagnetic radiation crossing the optical system in operation. In the following description, “micrometer-range optical element” designates an optical element formed on a surface of a support having a maximum dimension, measured parallel to said surface, greater than 1 μm and smaller than 1 mm. In the following description, a film or a layer is said to be oxygen-tight when the permeability of the film or of the layer to oxygen at 40° C. is smaller than 1.10-1 cm3/(m2.day). The permeability to oxygen may be measured according to the ASTM D3985 method entitled “Standard Test Method for Oxygen Gas Transmission Rate Through Plastic Film and Sheeting Using a Coulometric Sensor”. In the following description, a film or a layer is said to be water-tight when the permeability of the film or of the layer to water at 40° C. is smaller than 1.10-1 g/(m2*day). The permeability to water may be measured according to the ASTM F1249 method entitled “Standard Test Method for Water Vapor Transmission Rate Through Plastic Film and Sheeting Using a Modulated Infrared Sensor”.

Embodiments of optical systems will now be described for optical systems comprising an array of micrometer-range optical elements in the case where each micrometer-range optical element corresponds to a micrometer-range lens, or microlens, formed of two dioptres. It should however be clear that these embodiments may also be implemented with other types of micrometer-range optical elements, where each micrometer-range optical element may for example correspond to a micrometer-range Fresnel lens, to a micrometer-range index gradient lens, or to a micrometer-range diffraction grating.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.7 μm.

To simplify the description, unless otherwise specified, a manufacturing step is designated in the same way as the structure obtained at the end of the step.

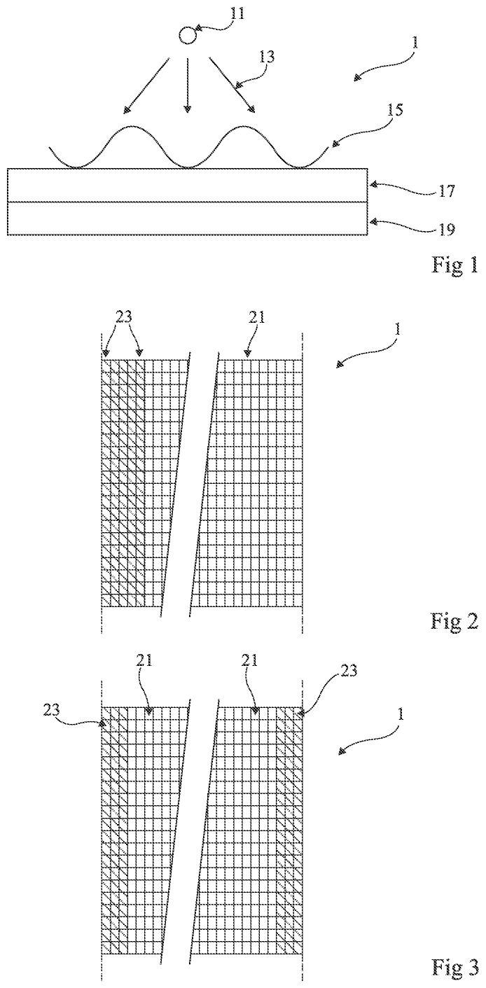

FIG. 1 illustrates in a partial simplified cross-section view an embodiment of an image acquisition system.

Acquisition system 1 comprises from top to bottom:

a light source 11 which emits a radiation 13;

an object 15;

an optical filter 17; and a

an image sensor 19, for example, a complementary metal oxide semiconductor, CMOS, sensor or a sensor made up of thin film transistors (TFT), which may be coupled to inorganic (crystal silicon for a CMOS sensor or amorphous silicon for a TFT sensor) or organic photodiodes.

Image acquisition system 1 further comprises circuits, not shown, for processing the signals supplied by image sensor 19, comprising, for example, a microprocessor.

Light source 11 is illustrated above object 15. It may however, as a variant, be located between object 15 and optical filter 17.

Radiation 13 is for example in the visible range and/or in the infrared range. It may be a radiation of a single wavelength or a radiation of a plurality of wavelengths (or wavelength range).

The photodiodes of image sensor 19 generally form a pixelated array. Each photodiode defines a pixel of image sensor 19. Within the array, the photodiodes are for example aligned in rows and in columns.

Some of the photodiodes of the array are generally used as a reference to only detect and record the noise of sensor 19 and of its electronic system. The noise is then deduced from the signals captured by the other photodiodes of sensor 19 to correct them. For this purpose, the radiation incident on the reference photodiodes is generally cut off (absorbed or reflected) by an opaque mask.

In conventional embodiments, the mask is generally positioned next to optical filter 17, that is, it covers sensor 19 outside of the optical filter. The mask is generally coplanar to optical filter 17.

In the following description, the term “pixel” is used to designate a photodiode, the expression “reference pixel” is used to designate a photodiode receiving no useful light radiation and the expression “useful pixel” is used to designate a pixel which delivers a useful signal of the captured image.

FIG. 2 illustrates in a partial simplified top view an embodiment of an image acquisition system 1.

More particularly, FIG. 2 illustrates an example of distribution of useful pixels 21 and of reference pixels 23 within an image acquisition system 1.

Pixels 21 and 23 are preferably aligned in rows and columns. For an image acquisition system 1 capable of adapting, for example, on a cell phone having a 6-inch screen, pixels 21 and 23 are for example organized in approximately 2,500 rows and approximately 1,300 columns for an imager having a 500-dpi resolution (that is, a 50.8-μm pixel pitch) The resolution of the image may for example vary between 254 dpi (that is, a 100-μm pixel pitch) and 1,000 dpi (that is, a 25-μm pixel pitch).

Pixels 21 and 23 are organized in the array so that at least one reference pixel 23 is present per row. Reference pixels 23 are all aligned in same columns. For example, from approximately 4 columns to approximately 64 columns only comprise reference pixels 23. Preferably, from approximately 16 columns to approximately 32 columns only comprise reference pixels 23.

In the embodiment illustrated in FIG. 2, the columns of reference pixels 23 are all adjacent and located on one of the edges of system 1 (on the left-hand side of system 1 in the orientation of FIG. 2).

FIG. 3 illustrates in a partial simplified top view another embodiment of an image acquisition system.

The embodiment illustrated in FIG. 3 is substantially identical to the embodiment illustrated in FIG. 2, with the difference that the columns of reference pixels 23 are located on the two edges of system 1. Preferably, a same number of columns of reference pixels 23 is present in each edge of system 1.

In the embodiments of FIGS. 2 and 3, the electronic noise is detected by all the photodiodes of reference pixels 23. The electronic noise detected by photodiodes of reference pixels 23 of same row is averaged. The average noise is then used to correct the useful signals detected by the photodiodes of the useful pixels 21 of the same row.

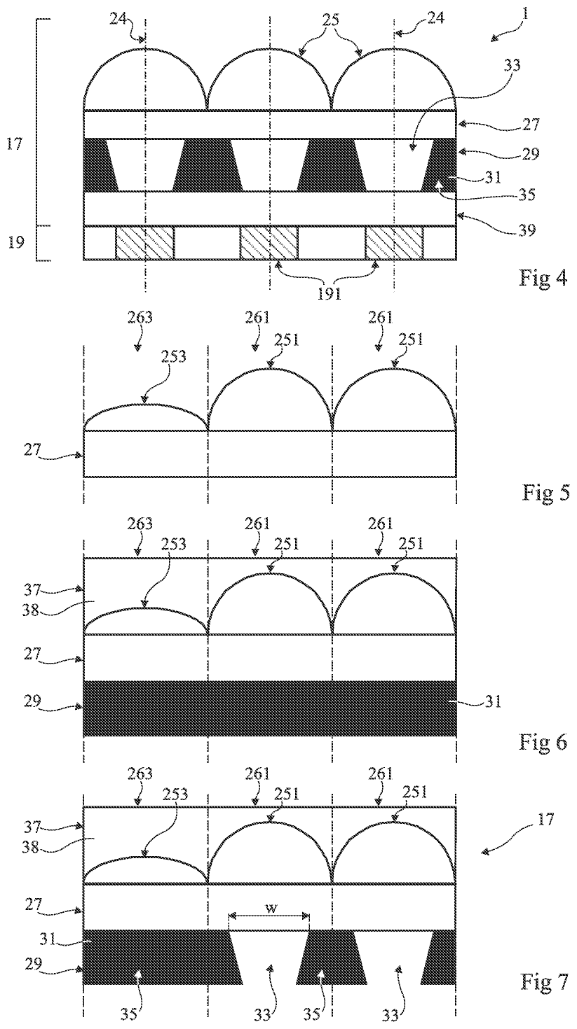

FIG. 4 illustrates in a partial simplified cross-section view an embodiment of an image acquisition system.

The image acquisition system 1 illustrated in FIG. 4 comprises:

an angular filter 17; and

image sensor 19 comprising photodiodes or photodetectors 191.

Angular filter 17 comprises from top to bottom in the orientation of FIG. 4:

an array of lenses 25;

a substrate or support 27; and

a first layer 29 of a first resin 31 comprising opening 33, or holes, and walls 35.

The described embodiments take as an example the case of an optical filter 17 forming an angular filter. However, such embodiments may apply to other types of optical filters such as, for example, a red green blue RGB color filter.

Angular 17 is capable of filtering the incident radiation according to the incidence of the radiation relative to the optical axes 24 of lenses 25. Angular filter 17 is adapted so that each photodetector 191 of image sensor 19 only receives the rays having respective incidences relative to the respective optical axes 24 of the lenses 25 associated with photodetector 191 smaller than a maximum incidence angle smaller than 45°, preferably smaller than 30°, more preferably smaller than 10°, more preferably still smaller than 4°. Angular filter 17 is capable blocking the rays of the incident radiation having respective incidences relative to the optical axes 24 of the lenses 25 of filter 17 greater than the maximum incidence angle.

Each opening 33 is preferably associated with a single lens 25. The optical axes 24 of lenses 25 are preferably aligned with the centers of the openings 33 of first layer 29. The diameter of lenses 25 is preferably greater than the maximum size of the cross-section (perpendicular to the optical axis of lenses 25) of openings 33.

In the example of FIG. 4, each photodetector 191 is shown as being associated with a single opening 33, the center of each detector 191 being aligned with the center of the opening 33 associated therewith. In practice, the resolution of angular filter 17 is at least twice greater than the resolution of image sensor 19. In other words, the system comprises at least twice more lenses 25 (or openings 33) than photodetectors 191. Thus, a photodiode 191 (FIG. 4) is associated with at least two lenses 25 (or openings 33).

In the present disclosure, “zone” designates each portion of filter 17 comprising at least one lens 25 and the underlying layers. For example, a zone is associated with a single pixel but a pixel is associated with at least two zones.

Each zone has a surface area substantially identical to the surface area of the lens 25 associated with the zone. Further, first zones correspond to the portions of optical filter 17 opposite reference pixels 23 (FIGS. 2 and 3) and second zones correspond to the portions of optical filter 17 opposite useful pixels 21 (FIGS. 2 and 3).

In the following description, the upper surface of a structure or of a layer, in the orientation of FIG. 4, is considered as being the front side and the lower surface of the structure or of the layer, in the orientation of FIG. 4, is considered as being the back side.

FIGS. 5 to 7 schematically and partially illustrate successive steps of an example of a method of manufacturing an angular filter 17 according to a first implementation mode.

FIG. 5 illustrates in a partial simplified cross-section view a step of the first implementation mode of the method of manufacturing an angular filter 17.

More particularly, FIG. 5 shows an initial structure comprising an array of coplanar first lenses 253 and second lenses 251 and substrate 27.

Substrate 27 may be made of a transparent polymer which does not absorb at least the considered wavelengths, here in the visible and infrared range. The polymer may in particular be polyethylene terephthalate PET, poly(methyl methacrylate) PMMA, a cyclic olefin polymer (COP), a polyimide (PI), or a polycarbonate (PC). The thickness of substrate 27 may for example vary from 1 to 100 μm, preferably from 20 to 100 μm. Substrate 27 may correspond to a colored filter, to a polarizer, to a half-wave plate, or to a quarter-wave plate.

Lenses or microlenses 251 and 253, on top of and in contact with substrate 27, may be made of silica, of PMMA, of positive resist, of PET, of polyethylene naphthalate (PEN), of COP, of polydimethylsiloxane (PDMS)/silicone, of epoxy resin, or of acrylate resin. Microlenses 251 and 253 may be formed by flowing of resist blocks. Microlenses 251 and 253 may further be formed by molding on a layer of PET, PEN, COP, PDMS/silicone, of epoxy resin, or of acrylate resin. Lenses 251 and 253 may be formed by printing.

Microlenses 251 and 253 are converging lenses, each having a focal distance f in the range from 1 μm to 100 μm, preferably from 20 μm to 70 μm.

In the embodiment illustrated in FIG. 5, microlenses 251 and 253 are not identical. Indeed, the radius of curvature of first lenses 253 is greater than the radius of curvature of second lenses 251. The height of lenses 253 is for example smaller than the height of lenses 251.

First lenses 253 are assigned to the first zones 263 (reference zones) and second lenses 251 are assigned to second zones 261.

According to another embodiment, not shown, the radius of curvature of first lenses 253 may be smaller than the radius of curvature of second lenses 251. The height of lenses 253 then is, for example, greater than the height of lenses 251.

FIG. 6 illustrates in a partial simplified cross-section view another step of the first implementation mode of the method of manufacturing an angular filter 17.

More particularly, FIG. 6 illustrates a step of deposition of a film 37, on the front surface of the structure illustrated in FIG. 5, and of the opaque layer 29 of first resin 31 on the back side of this same structure.

Film 37 of a second material 38 is deposited on the front side of the structure obtained at the end of the step of FIG. 5. Film 37 enables to planarize the front side of the structure. Film 37 further enables to modify the focal distance of the underlying lenses 251 and 253 to improve their convergence. Film 37 is for example, transparent to the radiations detected by the photodetectors (191, FIG. 4) and has a refraction index different from the refraction index of air. Film 37 may be obtained from an optically clear adhesive (OCA), particularly a liquid optically clear adhesive (LOCA), or a material having a low refraction index, or epoxy/acrylate glue. Preferably, film 37 follows the shape of the microlenses (251 and 253) and is made of the material 38 having a low refraction index, lower than that of the material of microlenses 251 and 253.

Film 37 is for example deposited by centrifugation and then crosslinked by an exposure to UV rays.

Layer 29 is for example deposited full plate across a thickness in the range, for example, from approximately 1 μm to approximately 1 mm, preferably in the range from approximately 12 μm to approximately 15 μm. Layer 29 is for example deposited by centrifugation, by coating, or printing.

Opaque layer 29 for example has a transmittance lower than approximately 0.1%, the transmittance preferably being lower than approximately 0.00001%.

According to an embodiment, resin 31 is positive resist, for example, a colored or black DNQ-Novolack resin, or a DUV (Deep Ultraviolet) resist. DNQ-Novolack resins are made up of a mixture of diazonaphtoquinone (DNQ) and of a novolack resin (phenolformaldehyde resin). DUV resins may comprise polymers made up of polyhydroxystyrenes.

FIG. 7 illustrates in a partial simplified cross-section view another step of the first implementation mode of the method of manufacturing an angular filter 17.

More particularly, FIG. 7 illustrates a step of forming opening 33 in layer 29.

An embodiment of a method of manufacturing openings 33 comprises the step of:

forming openings 33 in layer 29 by exposure of first resin 31 (photolithography), by its front side, to light (UV) collimated through the array of microlenses 251 and 253; and

removing, by development, the exposed portions of resin 31.

According to this embodiment, microlenses 251 and 253 and substrate 27 are preferably made of materials transparent over the wavelength range corresponding to the wavelengths used during the exposure.

First microlenses 253 and second microlenses 251 do not have the same effects, during the exposure, on the incident light rays. Indeed, second microlenses 251 are sized (height, radius of curvature, and focal distance) so that the emergent rays converge (focus) at a point in layer 29. First lenses 253 are however sized so that emergent rays converge at a point outside of layer 29. Such a focusing difference is essentially due to the difference between the radiuses of curvature of the first 253 and second lenses 251.

First resin 31 is positive, that is, the portion exposed to UV rays becomes soluble in a developer. More particularly, a minimum UV dose locally absorbed by resin 31, during the exposure time, is necessary for the resin to be able to be dissolved by the developer.

Due to the differences between the radiuses of curvature and the focal distances, the UV dose absorbed, during the exposure, by the portion of layer 29 underlying first lenses 253 is different from the UV dose absorbed, during the exposure, by the position of layer 29 underlying second lenses 251.

The exposure time is, in the embodiment of FIG. 7, defined so that:

the UV dose absorbed by the portions of layer 29 underlying second lenses 251 reaches the minimum dose; and

the UV dose absorbed by the portions of layer 29 underlying first lenses 253 does not reach the minimum dose.

Thus, openings 33 are for example formed in layer 29 only in the portions underlying second lenses 251, that is, in second zones 261. Second zones 261 are thus transparent.

The portions of layer 29 underlying first lenses 253, that is, the portions of layer 29 of first zones 263, are, preferably, solid and opaque.

In FIG. 7, openings 33 are shown with a cross-section by a trapezoidal cross-section view. Generally, according to the exposure parameters, the cross-section of openings 33, in cross-section view, may be square, triangular, rectangular. Further, the cross-section of openings 33, in top view, may be circular, oval, or polygonal, for example, triangular, square, or rectangular. The cross-section of openings 33, in top view, is preferably circular. Openings 33 may have substantially the same dimensions. Call “w” the width or the diameter of openings 33 (measured at the base of the openings, that is, at the interface with substrate 27). Width w may vary from 5 μm to 30 μm. Width w is preferably in the range from 5 μm to 20 μm, for example, equal to approximately 10 μm.

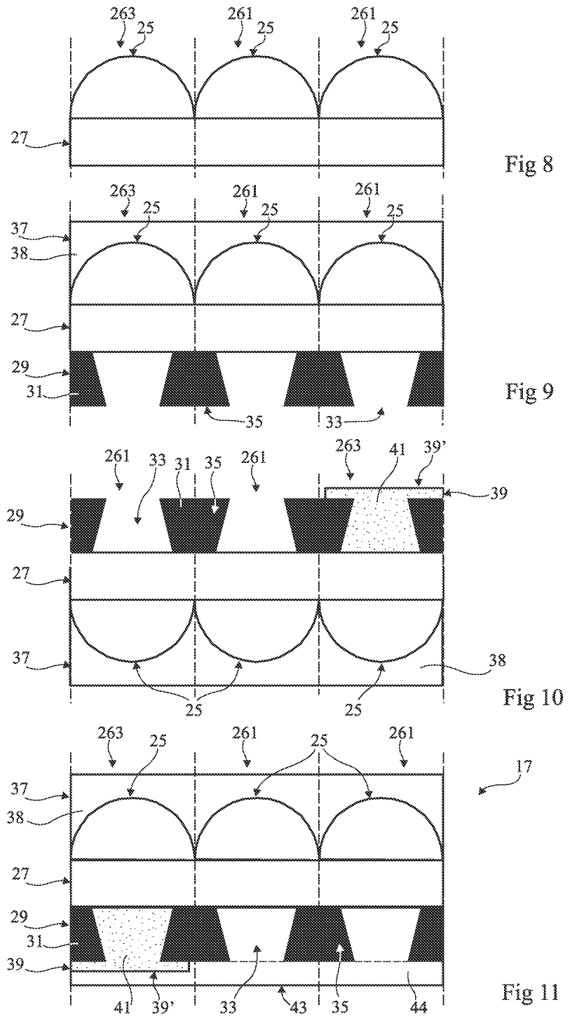

FIGS. 8 to 11 schematically and partially illustrate successive steps of an example of a method of manufacturing an angular filter 17 according to a second implementation mode.

The second implementation mode differs from the first implementation mode by the fact that first zones 263 are made opaque due to the forming of a second opaque layer 39 opposite the corresponding lenses 25, on the back side of the structure, in openings 33. Lenses 25 are, in the second embodiment, all identical to the second lenses 251 of the first implementation mode.

FIG. 8 illustrates in a partial simplified cross-section view a step of the second implementation mode of the method of manufacturing an angular filter 17.

More particularly, FIG. 8 illustrates an initial structure identical to the initial structure of the method according to the first implementation mode (FIG. 5), with the difference that all lenses 25 are substantially identical.

FIG. 9 illustrates in a partial simplified cross-section view another step of the second implementation mode of the method of manufacturing an angular filter 17.

More particularly, FIG. 9 illustrates a step of deposition of film 37 on the front side of the structure illustrated in FIG. 8 and of forming of layer 29 of first resin 31, comprising array 33 of openings, on the back side of the initial structure illustrated in FIG. 8. This step is substantially identical to the steps of FIGS. 6 and 7 of the first implementation mode altogether, with the difference that, in the second implementation mode, an opening 33 is formed opposite each lens 25.

FIG. 10 illustrates in a partial simplified cross-section view another step of the second implementation mode of the method of manufacturing an angular filter 17.

More particularly, FIG. 10 illustrates a step of forming of the second layer 39 of a first material 41 on the back side of the structure obtained at the end of the steps of FIGS. 8 and 9.

It should be noted that in the example of FIG. 10, the orientation of the structure is inverted with respect to the cross-section views of the previous drawings.

In the embodiment illustrated in FIG. 10, the second layer 39 of first material 41 is deposited on the back side of the structure obtained at the end of the steps of FIGS. 8 and 9. Second layer 39 is locally deposited in all openings 33 opposite the lenses 25 of first zones 263. Second layer 39 is not continuous. Thus, each opening 33 of first zones 263 comprises a portion 39′ of second layer 39.

Material 41 is an opaque material for example having a transmittance lower than approximately 0.1%, the transmittance preferably being lower than approximately 0.00001%.

Material 41 is for example a metal or an ink. Material 41 may be made up of silver, on copper, or of graphene. Material 41 may be made up of metal nanoparticles or of dyes.

Material 41 for example has the same composition as first resin 31.

Layer 39 is for example deposited by an inkjet technique, by silk screening, by a syringe-assisted local deposition technique, by flexography, by heliography, or by a spray printing technique.

Layer 39 is for example deposited by centrifugation and then exposed (photolithography) and developed so that only portions 39′ remain.

According to another embodiment, not shown in FIG. 10, second layer 39 may be formed before the forming of layer 29. Portions 39′ are thus locally formed opposite the lenses 25 of first zone 263 on the back side of substrate 27. Each portion 39′ of second layer 39 extends on a surface substantially identical to the surface of lens 25 having portion 39′ associated therewith. Layer 29 is then formed and covers either portions 39′ or the back side of substrate 27 between portions 39′. The step of forming openings 33 is similar to the step described in relation with FIG. 9. In view of the opacity of layer 39, the structure obtained at the end of this step is not similar to the structure illustrated in FIG. 9. Indeed, openings 33 only form opposite the lenses 25 of second zones 261.

FIG. 11 illustrates in a partial simplified cross-section view another step of the second implementation mode of the method of manufacturing an angular filter 17.

More particularly, FIG. 11 illustrates a step of forming of a third layer 43, made of a third material 44, on the back side of the structure obtained at the end of the steps of FIGS. 8 to 10.

Optionally, the openings 33 which are not filled are filled with layer 39 of air or of a filling material, at least partially transparent to the radiation detected by the photodetectors (191, FIG. 4), for example, PDMS. As a variant, openings 33 may be filled with a partially absorbing material to chromatically filter the rays angularly filtered by angular filter 17.

At the end of the step illustrated in FIG. 10 or after the optional filling of openings 33, the back side of the structure is submitted to a full-plate deposition of third layer 43. In other words, first layer 29, second layer 39, and possibly the filling material, are covered with third layer 43. The lower surface of third layer 43 (in the orientation of FIG. 11) is, after this step, substantially planar. Openings 33 are filled with this layer 43 if the step of filling of openings 33 has not been carried out previously.

The material 44 of layer 43 is preferably at least partially transparent to the radiation detected by the photodetectors (191, FIG. 4). Material 44 is for example made up of PDMS, of epoxy glue, of acrylate, or of a resin known under trade name SU8. The filling material, used during the optional filling of openings 33, and the material 44 of layer 43 may have the same composition or different compositions.

According to another embodiment, not shown, second layer 39 is formed after the optional step of filling of openings 33 and before the step of deposition of third layer 43. The portions 39′ of layer 39 are locally formed opposite the lenses 25 of first zones 263 on the back side of openings 33. Each portion 39′ of second layer 39 extends on a surface substantially identical to the surface of lens 25 having portion 39′ associated therewith.

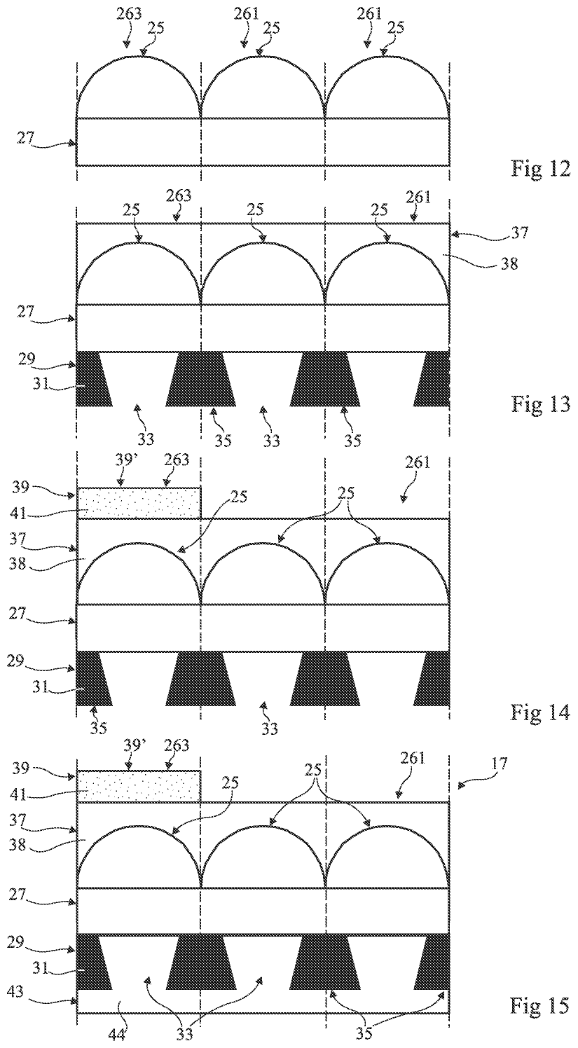

FIGS. 12 to 15 schematically and partially illustrate successive steps of an example of a method of manufacturing an angular filter 17 according to a third implementation mode.

The third implementation mode differs from the second implementation mode by the fact the first zones 263 are made opaque due to the forming of opaque second layer 39, opposite the lenses 25 of first zones 263, on the front side of the structure.

FIG. 12 illustrates in a partial simplified cross-section view a step of the third implementation mode of the method of manufacturing an angular filter 17.

More particularly, FIG. 12 illustrates an initial structure identical to the initial structure of the method according to the second implementation mode shown in FIG. 8.

FIG. 13 illustrates in a partial simplified cross-section view another step of the third implementation mode of the method of manufacturing an angular filter 17.

More particularly, FIG. 13 shows a step of deposition of film 37 on the front side of the structure illustrated in FIG. 12 and of forming of first layer 29, of first resin 31, comprising array 33 of openings on the back side of the initial structure illustrated in FIG. 12.

This step is substantially identical to the step illustrated in FIG. 9 of the method according to the second implementation mode.

FIG. 14 illustrates in a partial simplified cross-section view another step of the third implementation mode of the method of manufacturing an angular filter 17.

More particularly, FIG. 14 illustrates a step of deposition of second layer 39, of first material 41, on film 37, on the structure obtained at the end of the steps of FIGS. 12 and 13, opposite the lenses 25 of first zones 263.

Second layer 39, made of first material 41, is formed on the front side of film 37, opposite each lens 25 of first zone 263. Second layer 39 is not continuous but is divided into portions 39′. Each portion 39′ is located opposite a lens 25 of first zone 263. Each portion 39′ extends over a surface area substantially identical to the surface area of the lens 25 having said portion 39′ associated therewith. Material 41 is an opaque material for example having a transmittance lower than approximately 0.1%, the transmittance preferably being lower than approximately 0.00001%.

Material 41 is for example similar to the material 41 of the second implementation mode (FIG. 10).

Layer 39 is for example formed in the same way as the layer 39 of the second implementation mode.

Optionally, it may be envisaged to deposit a second film (not shown), having a composition identical to that of film 37, on the front side of the structure obtained at the end of the steps of FIGS. 12 to 14, to planarize said surface.

FIG. 15 illustrates in a partial simplified cross-section view another step of the third implementation mode of the method of manufacturing an angular filter 17.

More particularly, FIG. 15 illustrates a step of forming of third layer 43, made of third material 44, on the back side of the structure obtained at the end of the steps of FIGS. 12 to 14.

This step is substantially identical to the step illustrated in FIG. 11 of the method according to the second implementation mode.

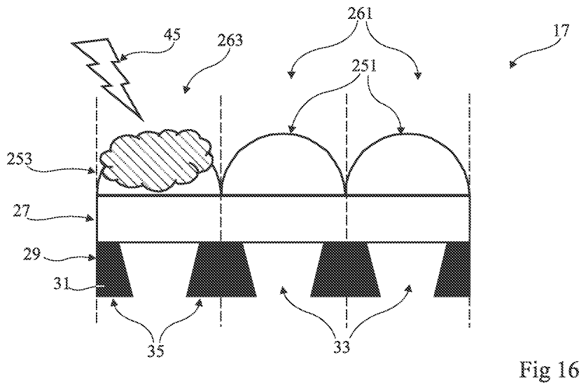

FIG. 16 illustrates in a partial simplified cross-section view a step of a fourth implementation mode of the method of manufacturing an angular filter 17.

The fourth implementation mode differs from the third implementation mode in that first zones 263 are made opaque by the deterioration of the first lenses 253 associated therewith. There thus is no second layer (39, FIG. 14).

More particularly, based on a structure identical to the structure illustrated in FIG. 13 of the method according to the third implementation mode, first lenses 253 are deteriorated. The deterioration of lenses 253 implies a modification of their optical properties, and particularly of the opacity.

The deterioration is for example performed by a laser selected to opacify the illuminated lenses (material sensitive to a specific wavelength or to a specific energy level of the laser).

According to an embodiment, the deterioration is performed on each first lens 253 and over the entire surface thereof.

According to an embodiment, the deterioration is performed, on each first lens 253, locally over a surface lower than its surface. The deterioration surface is for example centered on the optical axis of the considered lens 253.

Thus, after the deterioration, first lenses 253 have, locally or entirely, a transmittance lower than approximately 0.1%, preferably lower than approximately 0.00001%.

According to still another embodiment, substrate 27 is deteriorated by laser entirely or locally opposite first lenses 253.

The deterioration may be performed before or after the forming of layer 29.

After the step illustrated in FIG. 16, an additional step where third layer 43 is deposited on the back side of the structure similar to the step illustrated in FIG. 15 of the method according to the third embodiment may be provided.

An advantage of the described embodiments is that they enable to integrate an opaque mask to the angular filter. This particularly enables to do away with the distance separating the mask from the optical filter while decreasing the manufacturing cost of image acquisition systems. Indeed, the combination of the mask and of the optical filter enables to decrease the number of steps in the optical system assembly process.

Another advantage of the described embodiments is that the optical filters formed are compatible with usual image sensors.

Various embodiments and variants have been described. It will be understood by those skilled in the art that certain features of these various embodiments and variations may be combined and other variations will occur to those skilled in the art.

Finally, the practical implementation of the embodiments and variants described herein is within the capabilities of those skilled in the art based on the functional indications provided hereinabove.

1. An optical filter for an image sensor comprising:
an array of lenses formed of first and of second adjacent lenses and located on the first surface side of a substrate, the first lenses being comprised in first opaque zones and the second lenses being comprised in second zones, each first zone occupying a surface area equal to the surface area of at least one first lens comprised within this first zone;
openings, on the second surface side of said substrate, at least opposite the second lenses; and
an opaque layer opposite the first lenses on the second surface side of said substrate, having a surface equal to the surface of at least one first lens.

2. The optical filter according to claim 1, wherein the transmittance of the first areas is lower than approximately 0.1% or lower than approximately 0.00001%.

3. The optical filter according to claim 1, wherein each second area occupies a surface area equal to the surface area of at least one second lens.

4. The optical filter according to claim 1, wherein the first lenses and the second lenses are coplanar.

5. The optical filter according to claim 1, wherein the first zones and the second zones are adjacent and organized in rows and in columns.

6. The optical filter according to claim 5, wherein the first zones are organized in columns which are adjacent and located on one of the sides of the filter.

7. The optical filter according to claim 5, wherein the first zones are organized in columns which are distributed on two edges of the filter.

8. The optical filter according to claim 1, wherein the radius of curvature of the first lenses is smaller than the radius of curvature of the second lenses.

9. The optical filter according to claim 1, wherein the radius of curvature of the first lenses is greater than the radius of curvature of the second lenses.

10. The optical filter according to claim 1, wherein the first lenses are locally deteriorated.

11. A method of manufacturing the optical filter according to claim 1, comprising, among others, the steps of:
forming, by printing, the array of lenses on the first surface side of the substrate;
depositing a first layer of a resist on the second surface side of the substrate; and
forming openings, in the first layer, by photolithography through the lenses.

12. The method according to claim 11, wherein the second layer is formed in the openings in the first zones or on the first or second surface side of said openings.

13. The method according to claim 11, wherein the second layer is formed in the first zones.

14. The method according to claim 11, wherein the first lenses are partially deteriorated by a laser.

15. A system comprising:
the optical filter according to claim 1, capable of being considered as an angular filter;
a source of a radiation; and
an image sensor comprising photodetectors capable of detecting said radiation.

16. A fingerprint sensor comprising the system according to claim 15.
